(19) United States
(12) Patent Application Publication
(10) Pub. No.: US 2008/0268608 A1
(43) Pub. Date: Oct. 30, 2008

(54) METHOD OF FABRICATING A FLASH MEMORY DEVICE

(75) Inventors: Suk Joong Kim, Icheon-si (KR); Whee Won Cho, Cheongju-si (KR); Jung Geun Kim, Seoul (KR); Seong Hwan Myung, Suwon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/951,926

(22) Filed: Dec. 6, 2007

(30) Foreign Application Priority Data
Apr. 25, 2007 (KR) 10-2007-0040332

(51) Int. Cl. H01L 21/76

(52) U.S. Cl. 438/424; 257/E21.545

(57) ABSTRACT

In a method of fabricating a flash memory device, after an isolation trench is formed, a bottom surface and sidewalls of the trench are gap-filled with a HARP film having a favorable step coverage. A wet etch process is performed such that the HARP film remains on the sidewalls of a tunnel dielectric layer, thereby forming a wing spacer. Accordingly, the tunnel dielectric layer can be protected and an interference phenomenon can be reduced because a control gate to be formed subsequently is located between floating gates.

### CROSS-REFERENCES TO RELATED APPLICATIONS

The present application claims priority to Korean patent application number 10-2007-40332, filed on Apr. 4, 2007, which is incorporated by reference in its entirety.

### BACKGROUND OF THE INVENTION

The present invention relates to flash memory devices and, more particularly, to a method of fabricating a flash memory device in which an interference phenomenon between floating gates can be reduced.

A NAND flash memory device includes a plurality of cells for storing data, which are connected in series to form a string. A drain select transistor and a source select transistor are formed between a cell string and a drain, and the cell string and a source, respectively. In a cell of the NAND flash memory device, a stack gate of a tunnel oxide layer, a floating gate, a dielectric layer, and a control gate is formed in a specific region on a semiconductor substrate. A junction is formed at both sides of the gate.

In the NAND flash memory device, the state of the cell is influenced by an operation of peri cells. Thus, maintaining a constant state of the cell is important. A phenomenon in which the state of a cell is changed due to the operation of peri cells, in particular a program operation, is referred to as an interference phenomenon. In other words, the interference phenomenon refers to a situation where a second cell adjacent to a first cell to be programmed is programmed, and a threshold voltage higher than the threshold voltage of the first cell is read when reading the first cell due to a capacitance effect caused by a change in charges of a floating gate of the second cell. Charges of a floating gate of a read cell are not changed, but the state of an actual cell appears distorted due to a change in the state of neighboring cells. The state of the cell is changed due to this interference phenomenon, which results in an increased failure rate and a low yield. Accordingly, the interference phenomenon is minimized by maintaining a constant state of a cell.

In a fabrication process of a general NAND flash memory device, a portion of an isolation layer and a floating gate is formed by a Self-Aligned Shallow Trench Isolation (SA-STI) process. This process is described with reference to FIG. 1.

A tunnel oxide layer 11 and a first polysilicon film 12 are formed over a semiconductor substrate 10. A specific region of the first polysilicon film 12 and the tunnel oxide layer 11 is etched. The semiconductor substrate 10 is etched to a predetermined depth, thereby forming trenches 13. The trenches are gap-filled with an insulating layer and a polishing process is performed to form isolation layers 14. A first oxide layer 15, a nitride layer 16, and a second oxide layer 17 are sequentially formed to complete a dielectric layer 18.

If the flash memory device is fabricated by the SA-STI process as described above, interference may occur between the first polysilicon films because the isolation layer is formed between the first polysilicon film, serving as a floating gate, and a neighboring first polysilicon film.

FIG. 2 illustrates the interference phenomenon and the coupling ratio depending on the height and distance between floating gates.

Referring to FIG. 2, inter-gate interference is proportional to a distance between floating gates and the height of the floating gate. In other words, if the distance between the floating gates is increased and the height of the floating gate is reduced, interference decreases. In contrast, if the height of the floating gate is reduced, an interface area of the floating gate and the control gate reduces and the coupling ratio decreases accordingly.

### BRIEF SUMMARY OF THE INVENTION

The present invention is directed to a method of fabricating a flash memory device. After an isolation trench is formed, a bottom surface and sidewalls of the trench are gap-filled with a High Aspect Ratio Process (HARP) film having a favorable step coverage. A wet etch process is performed causing the HARP film to remain on the sidewalls of a tunnel dielectric layer, such that a wing spacer is formed. Thus, the tunnel dielectric layer can be protected and an interference phenomenon can be reduced because a control gate to be formed subsequently is located between floating gates.

In one embodiment, a method of fabricating a flash memory device, includes sequentially forming a tunnel dielectric layer, an electron storage layer, and a hard mask over a semiconductor substrate; etching the hard mask, the electron storage layer, the tunnel dielectric layer, and a part of the semiconductor substrate to form a trench; gap-filling the trench with an insulating layer; etching a top surface of the insulating layer to control an Effective Field Height (EFH), wherein the insulating layer remains on sidewalls of the tunnel dielectric layer, such that a wing spacer is formed; forming a buffer layer on a resulting surface including the wing spacers; performing a chemical mechanical polishing (CMP) process to expose a top surface of the hard mask; and removing the hard mask and the buffer layer.

The forming of the trench includes etching an isolation region of the exposed semiconductor substrate to form a first trench; forming a spacer on sidewalls of the first trench; and forming a second trench having a width, which is narrower and deeper than a width of the first trench, in the isolation region between the spacers.

The insulating layer is formed of a HARP film having a favorable step coverage, and the insulating layer is formed of a SiO₂ film having a favorable step coverage.

The method further includes performing an annealing process before the wing spacer is formed after the insulating layer is formed. The annealing process is performed using N₂ gas or H₂gas, and is performed at a temperature range of 800 to 1000 degrees Celsius for 30 minutes to 1 hour.

The buffer layer is formed of a PSZ layer or a HSQ layer by a SOG method.

The gap-filling of the insulating layer is performed such that a bottom of the trench, which is lower than the electron storage layer, is gap-filled, and a top surface of the trench, which is at the same level as or higher than the electron storage layer, is formed on the sidewalls of the trench. A thickness the insulating layer ranges from 350 to 450 angstroms and a thickness on the sidewalls of the trench ranges from 150 to 200 angstroms.

### BRIEF DESCRIPTION OF THE DRAWINGS

FIG. 1 is a cross-sectional view illustrating a conventional method of fabricating a flash memory device;

FIG. 2 is a graph illustrating the relationship between interference and a coupling ratio depending on a height of a floating gate of a flash memory device and a space between the floating gates; and

FIGS. 3 to 11 are cross-sectional views illustrating a method of fabricating a flash memory device according to an embodiment of the present invention.

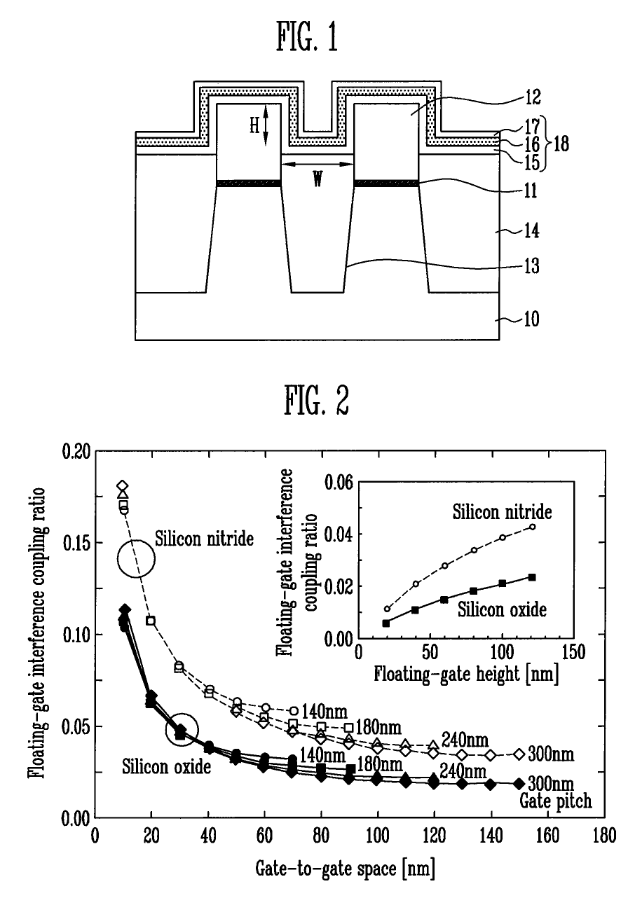

### DESCRIPTION OF SPECIFIC EMBODIMENTS

A specific embodiment according to the present invention is described with reference to the accompanying drawings.

FIGS. 3 to 11 are cross-sectional views illustrating a method of fabricating a flash memory device according to an embodiment of the present invention.

Referring to FIG. 3, a tunnel dielectric layer 102, an electron storage layer 104 and an isolation mask 112 are sequentially formed over a semiconductor substrate 100. The isolation mask 112 may have a stack structure of a buffer oxide layer 106, a nitride layer 108, and a hard mask 110. The hard mask 110 may be formed of a nitride matter, an oxide matter, SiON or amorphous carbon. The electron storage layer 104 forms a floating gate of the flash memory device, and may be formed of polysilicon or a silicon nitride layer. Alternatively, the electron storage layer 104 may be formed of any material capable of storing electrons.

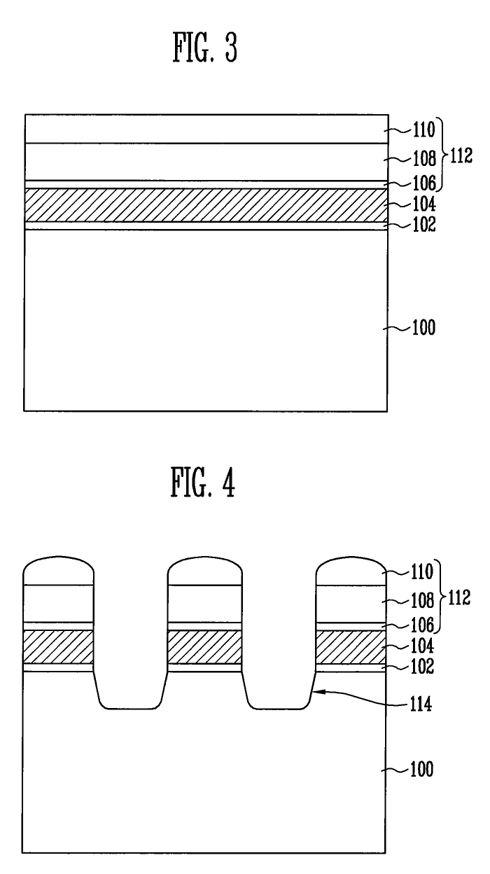

Referring to FIG. 4, the isolation mask 112, the electron storage layer 104, and the tunnel dielectric layer 102 of an isolation region are sequentially etched to expose the isolation region of the semiconductor substrate 100. Specifically, a photoresist (not shown) is coated on the isolation mask 112, and exposure and development processes are then performed to form a photoresist pattern (not shown) through which the isolation mask 112 of the isolation region is exposed. The isolation region of the isolation mask 112 is removed by an etch process employing the photoresist pattern. The photoresist pattern is then removed. The electron storage layer 104 and the tunnel dielectric layer 102 are etched by an etch process employing the isolation mask 112, so that the semiconductor substrate 100 of the isolation region is exposed. In the etch process of the nitride layer 108, the buffer oxide layer 106, the electron storage layer 104, and the tunnel dielectric layer 102, the hard mask 110 is also etched to a specific thickness.

The exposed semiconductor substrate 100 of the isolation region is etched by a first etch process, thereby forming first trenches 114. Each of the first trenches 114 may have a depth corresponding to ⅙ to ⅓ of a target depth. For example, the first trench 114 may be formed by etching the semiconductor substrate 100 to a depth of 50 to 2000 angstroms. The first etch process may also be performed so that the sidewall of the first trench 114 has a slope of 85 to 90 degrees.

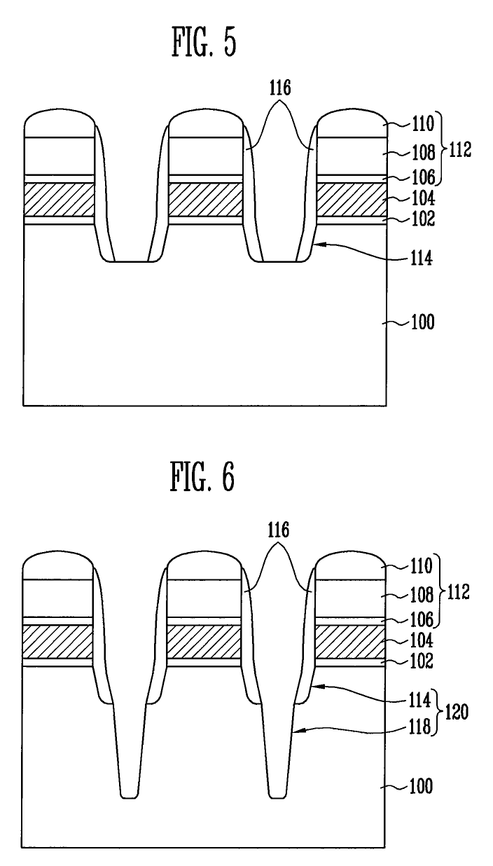

Referring to FIG. 5, an oxidization process may be carried out to recover etch damage on the sidewalls and the bottom surface of the first trench 114 due to the etch process of forming the first trench 114.

Thereafter, spacers 116 are formed on the sidewalls of the first trench 114. Specifically, after an insulating layer is formed on the entire surface including the first trenches 114, a blanket etch-back process is performed to form the spacers 116 such that the insulating layer remains on the sidewalls of the first trenches 114, but is removed from the bottom surface of the first trenches 114. The insulating layer also remains on the sidewalls of the electron storage layer 104 and the isolation mask 112. Consequently, the spacers 116 are formed on the sidewalls of the first trenches 114, the electron storage layer 104 and the isolation mask 112. The insulating layer may be formed of an oxide layer, a HTO oxide layer, a nitride layer or a mixture layer thereof. The oxide layer and the HTO oxide layer are formed by an oxidization process. In the event that the spacer 116 is used as an anti-oxidization layer, the spacer 116 may comprise nitride matter. An example in which the spacer 116 is used as the anti-oxidization layer is described below. The spacer 116 may be formed to a thickness in which the bottom surface of the first trench 114 is exposed between the spacers 116 in consideration of the width of the first trench 114. For example, the spacer 116 may be formed to a thickness corresponding to ⅙ to ¼ of the width of the first trench 114, or to a thickness of 50 to 1000 angstroms.

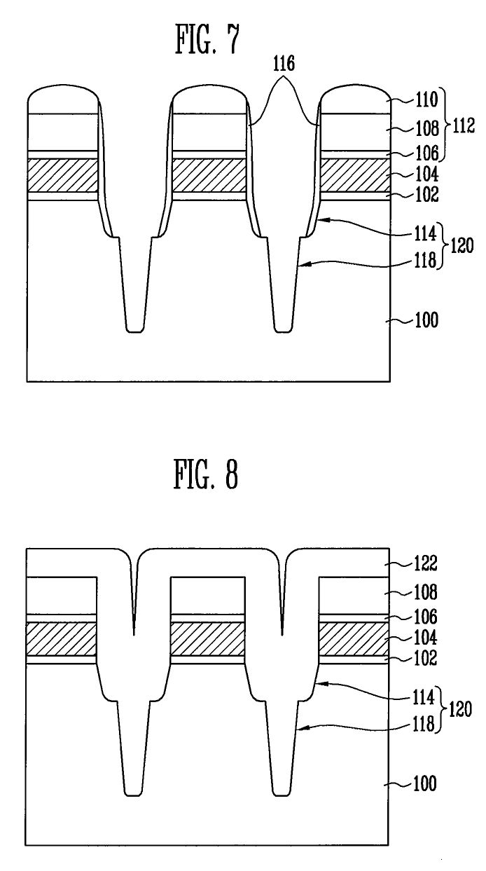

Referring to FIG. 6, the semiconductor substrate 100 at the bottom surface of the first trench 114, which is exposed between the spacers 116, is etched by an etch process employing the spacers 116 and the isolation mask 112, thereby forming second trenches 118. Each of the second trenches 118 may be formed to a depth of 500 to 20000 angstroms. Consequently, trenches 120 each having a top width larger than a bottom width are formed in the isolation region.

Referring to FIG. 7, the spacer 116 is etched to a specific thickness so that a gap between the spacers 116 is widened. The spacer 116 may be fully removed. In the event that the spacer 116 is formed of oxide matter, the spacer 116 may be etched using a fluoric acid solution. In the event that the spacer 116 is formed of nitride matter, the spacer 116 may be etched using a phosphoric acid solution. If the gap between the spacers 116 is widened, the aspect ratio decreases and, therefore, a gap-fill characteristic can be improved when an insulating layer for gap-filling the trenches 120 in a subsequent process is formed. The etch process of the spacer 116 may be performed by a wet etch or dry etch process employing an etchant.

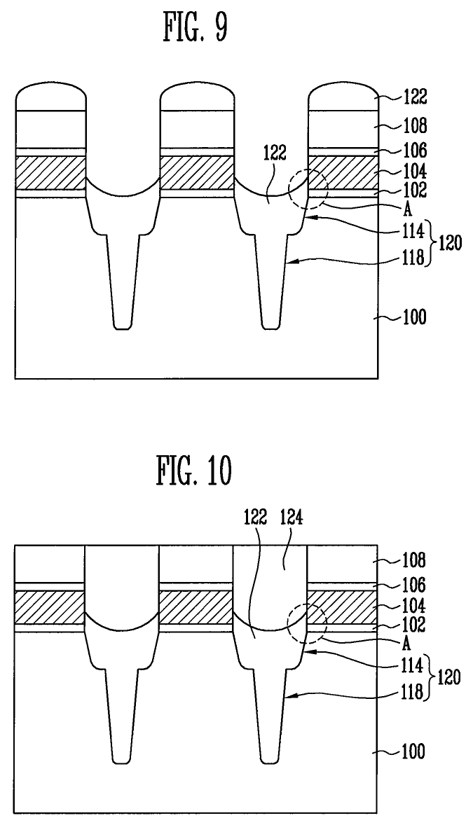

Referring to FIG. 8, after the hard mask 110 is removed, an insulating layer for isolation 122 is formed on the entire surface including the trenches 120. The insulating layer for isolation 122 may be formed using a HARP film having a favorable step coverage. A thickness of the insulating layer for isolation 122 measured from a flat surface may range from 350 to 450 angstroms, and a thickness of the insulating layer for isolation 122 measured from the sidewalls of the trenches 120 may range from 150 to 200 angstroms. Alternatively, the insulating layer for isolation 122 may be formed using a SiO₂ film having a favorable step coverage. The insulating layer for isolation 122 gap-fills the bottom of the trench 120, that is, the bottom of the trench 120, which is at a lower level than the charge storage layer 104, but does not fully gap-fill the top of the trench 120 due to the thickness of the insulating layer for isolation 122.

An annealing process is then performed to improve the film quality of the insulating layer for isolation 122. The annealing process may be performed using N₂ gas or H₂O gas. The annealing process may be performed at a temperature range of 800 to 1000 degrees Celsius for 30 minutes to 1 hour.

Referring to FIG. 9, a wet etch process is performed to remove the insulating layer for isolation 122 formed on the top surface of the trench 120. The wet etch process may be carried out such that the top surface of the trench 120, that is, the insulating layer for isolation 122 formed on the sidewalls of the buffer oxide layer 106 and the nitride layer 108, is removed, but the insulating layer for isolation 122 formed on the sidewalls of the tunnel dielectric layer 102 remains, thereby forming an isolation layer 122 having a wing spacer A. As described above, the wet etch process can be performed to form the wing spacer A that protects the sidewalls of the tunnel dielectric layer 102 while controlling the EFH of the isolation layer 122.

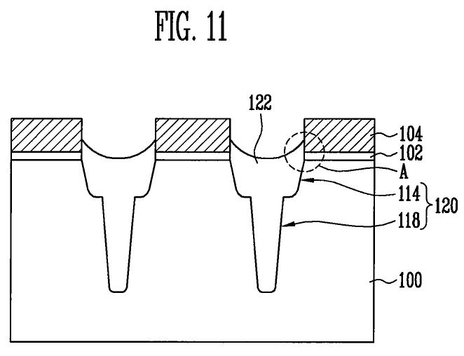

Referring to FIG. 10, a buffer layer 124 is formed on the entire surface including the isolation layer 122. The buffer layer 124 may be formed using a PSZ layer or a HSQ layer, which is formed by a silicon on glass (SOG) method having a high etch rate with respect to the isolation layer 122 during a subsequent etch process. In general, during an etch process using FN, the HARP film may have an etch rate of 2 angstroms/sec, but in the case of the PSZ layer, the HARP film may have an etch rate of 7 angstroms/sec. However, the difference in the etch rate can be controlled by the annealing process. The buffer layer 124 serves to prevent the collapse of a pattern due to an empty space at the top of the trench 120 in a subsequent CMP process. A CMP process is then performed to expose the nitride layer 108.

Referring to FIG. 11, the exposed nitride layer and the exposed buffer oxide layer are sequentially etched and removed. The buffer layer is removed by a wet or dry etch process. The wet etch process may be performed using FN.

Though not shown in the drawings, a dielectric layer and a conductive layer for a control gate are formed on the entire surface including the isolation layer 122.

According to an embodiment of the present invention, after an isolation trench is formed, a bottom surface and sidewalls of the trench are gap-filled with a HARP film having a favorable step coverage. A wet etch process is performed to cause the HARP film to remain on the sidewalls of a tunnel dielectric layer, such that a wing spacer is formed. Accordingly, the tunnel dielectric layer can be protected and an interference phenomenon can be reduced because a control gate to be formed subsequently is located between floating gates.

Although the foregoing description has been made with reference to a specific embodiment, it is to be understood that changes and modifications of the present invention may be made by one having ordinary skill in the art without departing from the spirit and scope of the present invention and appended claims.

What is claimed is:

1. A method of fabricating a flash memory device, the method comprising:
forming a tunnel dielectric layer and an electron storage layer over a semiconductor substrate;
forming a trench by etching the electron storage layer, the tunnel dielectric layer, and a portion of the semiconductor substrate;
forming an insulating layer such that the trench is gap-filled; and
etching a top surface of the insulating layer to control an effective field height (EFH), wherein the insulating layer remains on sidewalls of the tunnel dielectric layer, thereby forming a wing spacer.

2. The method of claim 1, wherein forming the trench comprises:
etching an isolation region of the exposed semiconductor substrate to form a first trench;
forming spacers on sidewalls of the first trench; and
forming a second trench having a width, which is narrower and deeper than a width of the first trench, wherein the second trench is formed in the isolation region between the spacers.

3. The method of claim 1, wherein the insulating layer is formed of a High Aspect Ratio Process (HARP) film having a favorable step coverage.

4. The method of claim 1, wherein the insulating layer is formed of a SiO₂ film having a favorable step coverage.

5. The method of claim 1, further comprising performing an annealing process before the wing spacer is formed and after the insulating layer is formed.

6. The method of claim 5, wherein the annealing process is performed using N₂ gas or H₂gas.

7. The method of claim 5, wherein the annealing process is performed in a temperature range of 800 to 1000 degrees Celsius for 30 minutes to 1 hour.

8. The method of claim 1, wherein the insulating layer is formed such that a bottom of the trench, which is lower than a level of the electron storage layer, is gap-filled, and a top surface of the trench, which is at least at the same level as the electron storage layer, is formed on the sidewalls of the trench.

9. The method of claim 1, wherein a thickness of the insulating layer is approximately 350 to 450 angstroms from the top surface thereof, and a thickness of the insulating layer on the sidewalls of the trench is approximately 150 to 200 angstroms.

10. A method of fabricating a flash memory device, the method comprising:
sequentially forming a tunnel dielectric layer, an electron storage layer, and a hard mask over a semiconductor substrate;
forming a trench by etching the hard mask, the electron storage layer, the tunnel dielectric layer, and a portion of the semiconductor substrate;
forming an insulating layer such that the trench is gap-filled;
etching a top surface of the insulating layer to control an EFH, wherein the insulating layer remains on sidewalls of the tunnel dielectric layer, thereby forming a wing spacer;
forming a buffer layer on a resulting surface including the wing spacer;
performing a chemical mechanical polishing (CMP) process to expose a top surface of the hard mask; and
removing the hard mask and the buffer layer.

11. The method of claim 10, wherein forming the trench comprises:
etching an isolation region of the exposed semiconductor substrate to form a first trench;
forming spacers on sidewalls of the first trench; and
forming a second trench having a width, which is narrower and deeper than a width of the first trench, wherein the second trench is formed in the isolation region between the spacers.

12. The method of claim 10, wherein the insulating layer is formed of a High Aspect Ratio Process (HARP) film having a favorable step coverage.

13. The method of claim 10, wherein the insulating layer is formed of a SiO₂ film having a favorable step coverage.

14. The method of claim 10, further comprising performing an annealing process before the wing spacer is formed and after the insulating layer is formed.

15. The method of claim 14, wherein the annealing process is performed using N₂ gas or H₂gas.

16. The method of claim 14, wherein the annealing process is performed at a temperature range of 800 to 1000 degrees Celsius for 30 minutes to 1 hour.

17. The method of claim 10, wherein the buffer layer is formed of a PSZ layer or a HSQ layer by a SOG method.

18. The method of claim 10, wherein removing the buffer layer is performed using a wet or dry etch process.

19. The method of claim 18, wherein the wet etch process is performed using FN.

20. The method of claim 10, wherein the insulating layer is formed such that a bottom of the trench, which is lower than the electron storage layer, is gap-filled, and a top surface of the trench, which is at least at the same level as the electron storage layer, is formed on the sidewalls of the trench.

21. The method of claim 10, wherein a thickness of the insulating layer from the top surface thereof is approximately 350 to 450 angstroms, and a thickness of the insulating layer on the sidewalls of the trench is approximately 150 to 200 angstroms.
